(19) United States
(12) Patent Application Publication
(10) Pub. No.: US 2013/0135003 A1
(43) Pub. Date: May 30, 2013

(54) Test Connector, Transmission Wire, Test System and Using Method

(71) Applicants: Hao Jin, Shenzhen (CN); Xiaoxin Zhang, Shenzhen (CN); Jungmao Tsai, Shenzhen (CN); Shaoyuan Zhang, Shenzhen (CN); MIngfeng Deng, Shenzhen (CN)

(72) Inventors: Hao Jin, Shenzhen (CN); Xiaoxin Zhang, Shenzhen (CN); Jungmao Tsai, Shenzhen (CN); Shaoyuan Zhang, Shenzhen (CN); MIngfeng Deng, Shenzhen (CN)

(73) Assignee: SHENZHEN CHINA STAR OPTOELLECTRONICS TECHNOLOGY CO., LTD., Shenzhen (CN)

(21) Appl. No.: 13/380,209

(22) PCT Filed: Dec. 3, 2011
(86) PCT No.: PCT/CN2011/083424

§ 371 Date: Dec. 22, 2011

(30) Foreign Application Priority Data
Nov. 29, 2011 (CN) 201110386586.6

(51) Int. Cl. G01R 31/27

(52) U.S. Cl. 324/760.02

(57) ABSTRACT

The present invention discloses a test connector, a transmission wire, a test system, and a using method. A test connector for a low voltage differential signal transmission wire comprises a signal wire interface matching with the low voltage differential signal transmission wire, and a PCB interface matching with a PCB plate to be tested, and the signal wire interface is electrically connected with the PCB interface. In the present invention, the test connector is inserted or pulled instead of a low voltage differential signal transmission (LVDS) connection; when damaged, only the test connector needs to be replaced, and the service life of the low voltage differential signal transmission (LVDS) wire is extended greatly. Because the cost of the test connector is only less than 10% of that of the LVDS wire, loss cost can be reduced.

### TECHNICAL FIELD

The present invention relates to the field of liquid crystal display, in particular to a test connector, a transmission wire, a test system, and a using method.

### BACKGROUND

Thin film transistor liquid crystal displays (TFT LCD) have already become the important displaying platforms of modern IT and video products. The thin film transistor liquid crystal displays have the following main working principle: liquid crystal molecules are deflected under voltage by loading appropriate voltage between liquid crystal layers combined by an array glass substrate and a color filter (CF) glass substrate; different penetration rates can be obtained by different voltage controls to realize display.

In a TFT LCD factory, products often need to be tested and products and signal sources need to be connected by the low voltage differential signal transmission (LVDS) wire. In prior art, the connection of one end of the low voltage differential signal transmission (LVDS) wire is directly inserted into the PCB plate of a product and the other end of the LVDS wire is inserted into a signal source. When a sample is replaced and tested, the connection inserting into the PCB needs to be pulled and inserted into another sample again. Because many tests are carried out every day, the low voltage differential signal transmission (LVDS) wire needs to be inserted and pulled frequently so that the low voltage differential signal transmission (LVDS) wire often becomes invalid due to connection damage.

### SUMMARY

The aim of the present invention is to provide a test connector, a transmission wire, a test system and a using method, which can extend the service life of the low voltage differential signal transmission (LVDS) wire.

The aim of the present invention is achieved by the following technical schemes:

A test connector for a low voltage differential signal transmission wire comprises a signal wire interface matching with the low voltage differential signal transmission wire, and a PCB interface matching with a PCB plate to be tested, and the signal wire interface is electrically connected with the PCB interface.

Preferably both ends of the PCB interface are provided with through holes. The through holes provide convenience for mechanized operation and manipulators can block the through holes on both sides for pulling and inserting the test connector.

Preferably the middle part of the PCB interface is provided with a flange and the extended length of the flange is consistent with the height of a pin for the test connector connected with the PCB plate to be tested. The flange is around a pin in the flange and can prevent the pin from being polluted by outside sundries to cause loose contact or short circuit; the extended length of the flange is consistent with the height of a pin for the test connector connected with the PCB plate to be tested, and positioning can be conducted by the flange and the end faces of the PCB interface on both sides of the flange after the test connector and the PCB plate to be tested are completely connected.

Preferably the signal wire interface is provided with a groove holding the low voltage differential signal transmission wire and both sides of the groove are provided with positioning bumps; after the connection of the low voltage differential signal transmission wire is inserted into the groove, the bumps can support the connection to avoid dropping, simultaneously ensure contact strength and promote the reliability of signal connection.

The connection of a low voltage differential signal transmission wire is connected with the test connector for a low voltage differential signal transmission wire.

A low voltage differential signal test system comprises the low voltage differential signal transmission wire.

Preferably the low voltage differential signal test system comprises a power supply, one end of the low voltage differential signal transmission wire corresponding to the connection is provided with an interface and the power supply is connected with the low voltage differential signal by the interface. Interface connection provides convenience for disassembly.

A using method for the low voltage differential signal transmission wire comprises the following steps:

Step A: test whether the PCB interface of the test connector for a low voltage differential signal transmission wire is normal; if normal, the PCB interface is connected with the PCB plate to be tested and start to test normally; if abnormal, turn to Step B;

Step B: the signal wire interface of the test connector for a low voltage differential signal transmission wire is removed from the low voltage differential signal transmission wire; the signal wire interface of a new test connector for a low voltage differential signal transmission wire is connected to the low voltage differential signal transmission wire and turn to Step A.

The research of the inventor of the present invention shows that the connection of the low voltage differential signal transmission wire is directly inserted into the PCB plate to be tested. Because replacing a test sample needs inserting and pulling the low voltage differential signal transmission (LVDS) wire once, the connection of the low voltage differential signal transmission (LVDS) wire is easy to damage. Once the low voltage differential signal transmission (LVDS) connection damages, the LVDS wire becomes invalid. In the present invention, the test connector is inserted or pulled instead of the low voltage differential signal transmission (LVDS) connection; when damaged, only the test connector needs to be replaced, and the service life of the low voltage differential signal transmission (LVDS) wire is extended greatly. Because the cost of the test connector is only less than 10% of that of the LVDS wire, loss cost can be reduced.

### DESCRIPTION OF FIGURES

FIG. 1 is the schematic diagram of the low voltage differential signal test system of the present invention;

FIG. 2 is the schematic diagram of the test connector of the present invention;

Wherein: 1. PCB plate to be tested, 2. test connector, 3. connection, 4. wire, 5. interface, 6. power supply. 7. signal wire interface, 8. PCB interface, 81. through holes, 82. flange.

### DETAILED DESCRIPTION

The present invention is further described by figures and the preferred embodiments as follows.

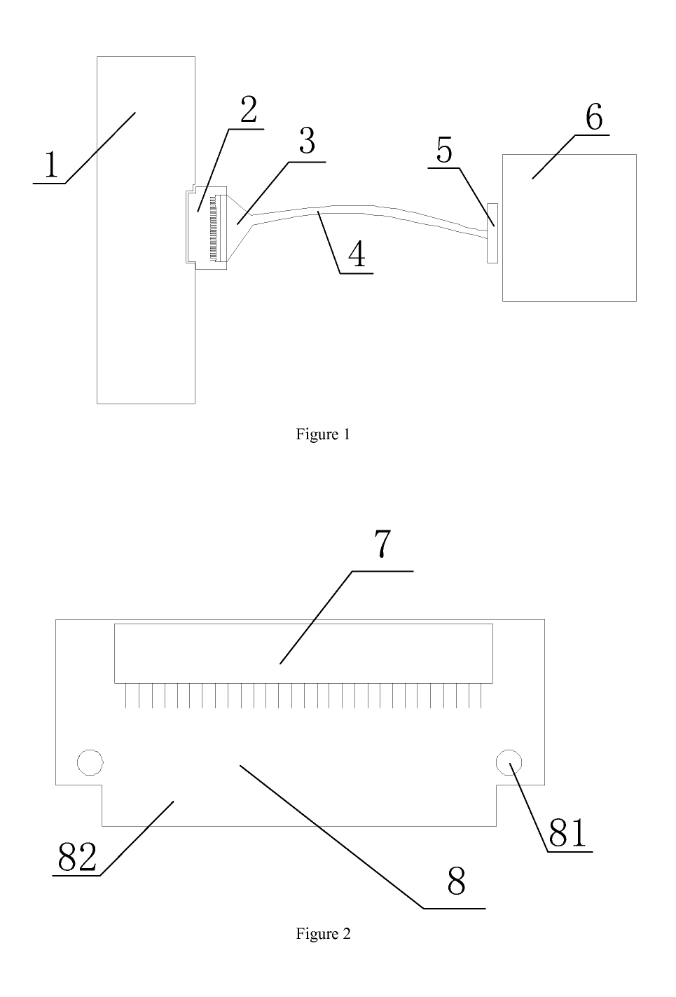

As shown in FIG. 1, a low voltage differential signal test system comprises a power supply 6 and a low voltage differential signal transmission wire connected with the power supply 6, one end of the low voltage differential signal transmission wire connected with the power supply 6 is provided with an interface 5 and the other end of the low voltage differential signal transmission wire is a connection 3; the interface 5 and the connection 3 are connected by a wire 4, the connection 3 is connected with a test connector 2 and the low voltage differential signal transmission wire is connected with a PCB plate to be tested by the test connector 2.

As shown in FIG. 2, the test connector 2 for a low voltage differential signal transmission wire comprises a signal wire interface 7 matching with the low voltage differential signal transmission wire and a PCB interface 8 matching with the PCB plate 1 to be tested. Both ends of the PCB interface are provided with through holes 81, the through holes 81 can provide convenience for mechanized operation and manipulators can block the through holes 81 for inserting and pulling the test connector 2. The middle part of the PCB interface 8 is provided with a flange 82, the extended length of the flange 82 is consistent with the height of a pin for the test connector 2 connected with the PCB plate 1 to be tested and the flange 82 is around a pin in the flange 82 and can prevent the pin from being polluted by outside sundries to cause loose contact or short circuit; the extended length of the flange 82 is consistent with the height of a pin for the test connector 2 connected with the PCB plate 1 to be tested, and positioning can be conducted by the flange 82 and the end faces of the PCB interface 8 on both sides of the flange 82 after the test connector 2 and the PCB plate 1 to be tested are completely connected. The signal wire interface 7 is provided with a groove holding the low voltage differential signal transmission wire and both sides of the groove are provided with positioning bumps; after the connection 3 of the low voltage differential signal transmission wire is inserted into the groove, the bumps can support the connection 3 to avoid dropping, simultaneously ensure contact strength and promote the reliability of signal connection.

A using method for the low voltage differential signal transmission wire comprises the following steps:

Step A: test whether the PCB interface of the test connector for a low voltage differential signal transmission wire is normal; if normal, the PCB interface is connected with the PCB plate to be tested and start to test normally; if abnormal, turn to Step B;

Step B: the signal wire interface of the test connector for a low voltage differential signal transmission wire is removed from the low voltage differential signal transmission wire; the signal wire interface of a new test connector for a low voltage differential signal transmission wire is connected to the low voltage differential signal transmission wire and turn to Step A.

The present invention is described in detail in accordance with the above contents with the specific preferred embodiments. However, this invention is not limited to the specific embodiments. For the ordinary technical personnel of the technical field of the present invention, on the premise of keeping the concept of the present invention, the technical personnel can also make simple deductions or replacements, and all of which should be considered to belong to the protection scope of the present invention.

We claim:

1. A test connector for a low-voltage differential signal transmission wire, comprising: a signal wire interface matching with the low voltage differential signal transmission wire, and a PCB interface matching with a PCB plate to be tested; said signal wire interface is electrically connected with the PCB interface.

2. The test connector for a low voltage differential signal transmission wire of claim 1, wherein both ends of said PCB interface are provided with through holes.

3. The test connector for a low voltage differential signal transmission wire of claim 1, wherein the middle part of said PCB interface is provided with a flange and the extended length of said flange is consistent with the height of a pin for said test connector connected with the PCB plate to be tested.

4. The test connector for a low voltage differential signal transmission wire of claim 1, wherein said signal wire interface is provided with a groove holding said low voltage differential signal transmission wire and both sides of said groove are provided with positioning bumps.

5. A low voltage differential signal transmission wire, the connection of said low voltage differential signal transmission wire is connected with a test connector for a low voltage differential signal transmission wire of claim 1 and said test connector comprises a signal wire interface matching with the low voltage differential signal transmission wire and a PCB interface matching with a PCB plate to be tested; said signal wire interface is electrically connected with said PCB interface.

6. The low voltage differential signal transmission wire of claim 5, wherein both ends of said PCB interface are provided with through holes.

7. The low voltage differential signal transmission wire of claim 5, wherein the middle part of said PCB interface is provided with a flange and the extended length of said flange is consistent with the height of a pin for said test connector connected with the PCB plate to be tested.

8. The low voltage differential signal transmission wire of claim 5, wherein said signal wire interface is provided with a groove holding said low voltage differential signal transmission wire and both sides of said groove are provided with positioning bumps.

9. The low voltage differential signal test system, comprising: a low voltage differential signal transmission wire of claim 5; the connection of said low voltage differential signal transmission wire is connected with the test connector for a low voltage differential signal transmission wire and said test connector comprises a signal wire interface matching with the low voltage differential signal transmission wire and a PCB interface matching with a PCB plate to be tested; said signal wire interface is electrically connected with said PCB interface.

10. The low voltage differential signal test system of claim 9, wherein both ends of said PCB interface are provided with through holes.

11. The low voltage differential signal test system of claim 9, wherein the middle part of said PCB interface is provided with a flange and the extended length of said flange is consistent with the height of a pin for said test connector connected with the PCB plate to be tested.

12. The low voltage differential signal test system of claim 9, wherein said signal wire interface is provided with a groove holding said low voltage differential signal transmission wire and both sides of said groove are provided with positioning bumps.

13. The low voltage differential signal test system of claim 9, wherein said low voltage differential signal test system comprises a power supply, opposite end of the connection of the low voltage differential signal transmission wire is provided with an interface and said power supply is connected with said low voltage differential signal by the interface.

14. The low voltage differential signal test system of claim 10, wherein said low voltage differential signal test system comprises a power supply, opposite end of the connection of the low voltage differential signal transmission wire is provided with an interface, the power supply is connected with said low voltage differential signal by the interface.

15. The low voltage differential signal test system of claim 11, wherein said low voltage differential signal test system comprises a power supply, opposite end of the connection of the low voltage differential signal transmission wire is provided with an interface, the power supply is connected with said low voltage differential signal by the interface.

16. The low voltage differential signal test system of claim 12, wherein said low voltage differential signal test system comprises a power supply, opposite end of the connection of the low voltage differential signal transmission wire is provided with an interface, the power supply is connected with said low voltage differential signal by the interface.

17. A using method for a low voltage differential signal transmission wire comprises the following steps:
Step A: test whether the PCB interface of the test connector for a low voltage differential signal transmission wire is normal; if normal, said PCB interface is connected with the PCB plate to be tested and start to test normally; if abnormal, turn to Step B;
Step B: the signal wire interface of the test connector for a low voltage differential signal transmission wire is removed from the low voltage differential signal transmission wire; the signal wire interface of a new test connector for a low voltage differential signal transmission wire is connected to the low voltage differential signal transmission wire and turn to Step A.
